(19) United States
(12) Patent Application Publication
(10) Pub. No.: US 2025/0210498 A1
(43) Pub. Date: Jun. 26, 2025

(54) REPACKAGING STRUCTURE

(71) Applicant: INDUSTRIAL TECHNOLOGY RESEARCH INSTITUTE, Hsinchu (TW)

(72) Inventors: Shih-Hsien WU, Taoyuan City (TW); Hsiu-Cheng CHANG, Taoyuan City (TW)

(73) Assignee: INDUSTRIAL TECHNOLOGY RESEARCH INSTITUTE, Hsinchu (TW)

(21) Appl. No.: 18/396,378

(22) Filed: Dec. 26, 2023

(30) Foreign Application Priority Data
Dec. 21, 2023 (TW) 112150008

(51) Int. Cl. H01L 23/498; H01L 23/00; H01L 25/065

(52) U.S. Cl. CPC H01L 23/49838; H01L 23/49816; H01L 24/08; H01L 24/16; H01L 25/0657; H01L 2224/08146; H01L 2224/08225; H01L 2224/16146; H01L 2224/16148; H01L 2225/06513; H01L 2225/06517; H01L 2924/15311

(57) ABSTRACT

A repackaging structure includes a substrate, at least one chip, a dielectric body, an electrical element and at least one conductive pillar. The substrate includes a plate, a plurality of mounting pads and a plurality of corresponding pads. The corresponding pads and the mounting pads are disposed on opposite surfaces of the plate. The corresponding pads correspond to the mounting pads. The chip is mounted on the substrate. The chip includes a plurality of chip leads. The chip leads are mounted on the mounting pads. The dielectric body covers the chip. The electrical element is disposed on the dielectric body. The conductive pillar electrically connects the electrical element and the substrate.

This non-provisional application claims priority under 35 U.S.C. § 119(a) on patent application No(s). 112150008 filed in Taiwan, R.O.C. on Dec. 21, 2023, the entire contents of which are hereby incorporated by reference.

### TECHNICAL FIELD

The disclosure relates to a repackaging structure, and relates to a repackaging structure for a chip.

### BACKGROUND

With the development of the semiconductor industry, the density of active elements on semiconductor chips gradually approaches the physical limit, and it is becoming increasingly difficult to make breakthroughs. Under this situation, manufacturers have developed various packaging solutions for desiring to have more functions in a repackaging structure with limited space.

In recent years, a high density interconnection substrate is used for semiconductor chip packaging. However, the high density interconnection substrate is relatively expensive. Furthermore, the manufacturers also needs to consider requirements of the mechanical bonding reliability and functions such as heat dissipation of this kind of substrate in the repackaging structure.

### SUMMARY

This disclosure is to provide a repackaging structure, which repackages a chip to improve performance and maintain a small size.

One embodiment of the disclosure provides a repackaging structure, including a substrate, including a substrate, at least one chip, a dielectric body, an electrical element and at least one conductive pillar. The substrate includes a plate, a plurality of mounting pads and a plurality of corresponding pads. The corresponding pads and the mounting pads are disposed on opposite surfaces of the plate. The corresponding pads correspond to the mounting pads. The chip is mounted on the substrate. The chip includes a plurality of chip leads. The chip leads are mounted on the mounting pads. The dielectric body covers the chip. The electrical element is disposed on the dielectric body. The conductive pillar electrically connects the electrical element and the substrate.

According to the repackaging structure as discussed in the above embodiments, the performance is improved and the volume is maintained small through repackaging. The chip is mounted on the substrate having the corresponding pads corresponding to the mounting pads, and the electrical element electrically connected to the substrate is disposed on the dielectric body covering the chip. Therefore, the functions of electrical element may be added to the repackaging structure while maintaining the original input and output status of the chip. Furthermore, the electrical element also has the effect of dissipating heat.

The above descriptions in the summary and the following detailed descriptions are used to demonstrate and explain the spirit and principle of the disclosure and provide a further explanation of the scope of claims of the disclosure.

### BRIEF DESCRIPTION OF THE DRAWINGS

The disclosure will become better understood from the detailed description given hereinbelow and the accompanying drawings which are given by way of illustration only and thus are not intending to limit the disclosure and wherein:

FIG. 1 is a schematic side cross-sectional view of a repackaging structure according to one embodiment of the disclosure;

FIG. 2 is a schematic side cross-sectional view of a repackaging structure according to another embodiment of the disclosure;

FIG. 3 is a schematic side cross-sectional view of a repackaging structure according to another embodiment of the disclosure;

FIG. 4 is a schematic top cross-sectional view taken along the line A-A in FIG. 3;

FIG. 5 is a schematic side cross-sectional view of a repackaging structure according to another embodiment of the disclosure;

FIG. 6 is a schematic side cross-sectional view of a repackaging structure according to another embodiment of the disclosure;

FIG. 7 is a schematic top cross-sectional view taken along the line B-B in FIG. 6;

FIG. 8 is a schematic side cross-sectional view of a repackaging structure according to another embodiment of the disclosure;

FIG. 9 is a schematic side cross-sectional view of a repackaging structure according to another embodiment of the disclosure;

FIG. 10 is a schematic top cross-sectional view of the repackaging structure shown in FIG. 9;

FIG. 11 illustrates the application of the repackaging structure shown in FIG. 9; and

FIG. 12 is a schematic side cross-sectional view of a repackaging structure according to another embodiment of the disclosure.

### DETAILED DESCRIPTION

Features and advantages of embodiments of the disclosure are described in the following detailed description, it allows the person skilled in the art to understand the technical contents of the embodiments of the disclosure and implement them, and the person skilled in the art can easily comprehend the purposes of the advantages of the disclosure. The following embodiments are further illustrating the perspective of the disclosure, but not intending to limit the disclosure.

The drawings may not be drawn to actual size or scale, some exaggerations may be necessary in order to emphasize basic structural relationships, while some are simplified for clarity of understanding, but the disclosure is not limited thereto. It is allowed to have various adjustments under the spirit of the disclosure. In addition, the spatially relative terms, such as “up”, “top”, “above”, “down”, “low”, “left”, “right”, “front”, “rear”, and “back” and the like, may be used herein for ease of description to describe the relationship of one element or feature to another element(s) of feature(s) as illustrated in the drawings. It will be understood that the spatially relative terms are intended to encompass orientations of the element or feature but not intended to limit the disclosure.

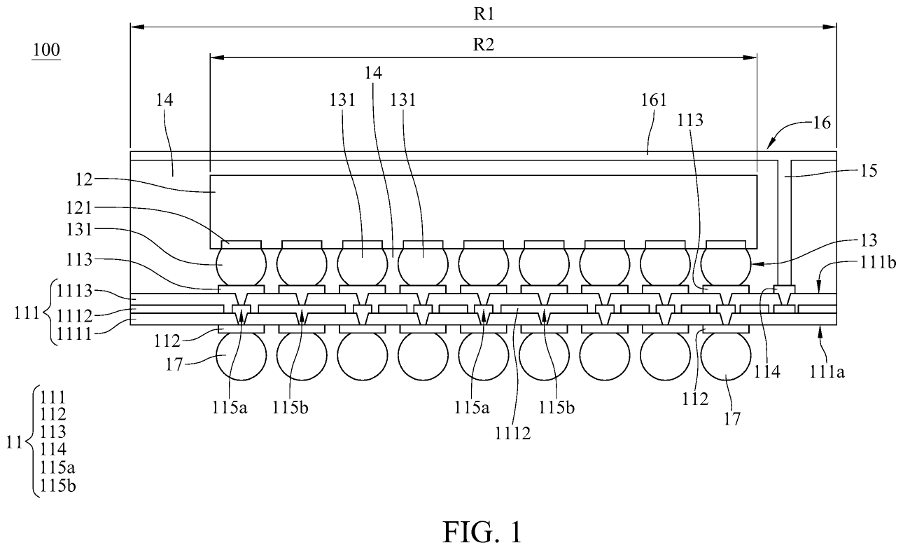

Please refer to FIG. 1. FIG. 1 is a schematic side cross-sectional view of a repackaging structure according to one embodiment of the disclosure. As shown in FIG. 1, the repackaging structure 100 includes a substrate 11, a chip 12, a buffer connection layer 13, a dielectric body 14, a conductive pillar 15 and an electrical element 16.

The substrate 11 includes a plate 111, a plurality of corresponding pads 112, a plurality of mounting pads 113, a ground pad 114 and a plurality of conductive-via-connection structures 115a, 115b. The plate 111 may be a redistribution layer (RDL). The plate 111 includes a first dielectric layer 1111, a ground layer 1112 and a second dielectric layer 1113. The plate 111 has a lower surface 111a and an upper surface 111b opposite to each other. The corresponding pads 112 are disposed on the lower surface 111a of the plate 111. The lower surface 111a is located at the first dielectric layer 1111. The ground layer 1112 is stacked on the first dielectric layer 1111. The second dielectric layer 1113 is stacked on the ground layer 1112 and the first dielectric layer 1111. The upper surface 111b is located at the second dielectric layer 1113. The mounting pads 113 are disposed on the upper surface 111b of the plate 111. The mounting pads 113 are electrically connected to the corresponding pads 112 through the conductive-via-connection structures 115a, 115b penetrating through the second dielectric layer 1113 and the first dielectric layer 1111. The ground layer 1112 is patterned so that the conductive-via-connection structures 115a are electrically insulated from the ground layer 1112, and the conductive-via-connection structures 115b are electrically connected to the ground layer 1112. The corresponding pads 112 vertically correspond to the mounting pads 113, and are electrically connected to the mounting pads 113 through the conductive-via-connection structures 115a, 115b, respectively. The ground pad 114 is disposed on the upper surface 111b of the plate 111 and electrically connected to the ground layer 1112. The conductive-via-connection structures 115a, 115b are structures in which a plurality of conductive vias are stacked on each other.

The chip 12 is mounted on the substrate 11 through the buffer connection layer 13. In this embodiment, the chip 12 is a packaging structure in which a die has been preliminarily packaged, but the disclosure is not limited thereto. In other embodiments, the chip 12 may also be an unpackaged die. In this embodiment, the buffer connection layer 13 includes a plurality of conductive solder blocks 131. The chip 12 includes a plurality of chip leads 121. The chip leads 121 are connected to the mounting pads 113 through the conductive solder blocks 131. A number of the chip leads 121 is equal to a number of the conductive solder blocks 131, and the number of the conductive solder blocks 131 is equal to a number of the mounting pads 113. A pitch between the chip leads 121 is substantially equal to a pitch between the mounting pads 113. The number of the mounting pads 113 is equal to a number of the corresponding pads 112. The pitch between the mounting pads 113 is substantially equal to a pitch between the corresponding pads 112. In this way, the mounting pads 113 correspond to the corresponding pads 112 in a one-on-one manner. The mounting pads 113 may include a plurality of signal mounting pads 113 and a plurality of non-signal mounting pads 113, and the corresponding pads 112 may include a plurality of signal corresponding pads 112 and a plurality of non-signal corresponding pads 112. In this case, the number of the plurality of signal mounting pads 113 is equal to the number of the plurality of signal corresponding pads 112. The non-signal mounting pads 113 and the non-signal corresponding pads 112 may be used for various non-signal functions such as grounding or power supply, and the number thereof is not limited, but a total number of the non-signal mounting pads 113 is equal to a total number of the non-signal corresponding pads 112. In addition, when the repackaging structure 100 suffers an impact, the buffer connection layer 13 may provide a buffering function for the chip 12, thereby preventing the chip 12 from being damaged due to impact.

In this embodiment, the number of the mounting pads 113 is equal to the number of the corresponding pads 112, but the disclosure is not limited thereto. In other embodiments, the number of the mounting pads 113 may be greater than the number of the corresponding pads 112, so that some of the chip leads 121 may correspond to one of the corresponding pads 112. Alternatively, in other embodiments, the corresponding pads 112 correspond to some of the mounting pads 113, and the other of the mounting pads 113 do not correspond to the corresponding pads 112. The chip leads 121 includes a plurality of signal leads and at least one other lead. The signal leads are mounted on the some of the mounting pads 113 corresponding to the corresponding pads 112, and the at least one other lead is mounted on the other of the mounting pads 113 not corresponding to the corresponding pads 112, so that the at least one other lead does not correspond to any of the corresponding pads 112. For example, the number of the corresponding pads 112/the number of the mounting pads 113=50%˜100%. The mounting pads 113 may include a plurality of signal mounting pads 113 and a plurality of non-signal mounting pads 113, and the corresponding pads 112 may include a plurality of signal corresponding pads 112 and a plurality of non-signal corresponding pads 112. In this case, a number of the signal mounting pads 113 is equal to a number of the signal corresponding pads 112. The non-signal mounting pads 113 and the non-signal corresponding pads 112 may be used for various non-signal functions such as grounding or power supply, but a total number of the non-signal mounting pads 113 is larger than a total number of the non-signal corresponding pads 112.

In this embodiment, the pitch between the mounting pads 113 is substantially equal to the pitch between the corresponding pads 112, but the disclosure is not limited thereto. In other embodiments, the pitch between the corresponding pads 112 may be larger than 100% of the pitch between the mounting pads 113 and smaller than or equal to 150% of the pitch between the mounting pads 113. In other embodiments, the pitch between the corresponding pads 112 may be larger than 100% of the pitch between the mounting pads 113 and smaller than or equal to 120% of the pitch between the mounting pads 113.

When the pitch between the mounting pads 113 is substantially equal to the pitch between the corresponding pads 112, a chip holder or a circuit board (not shown) originally designed to match the chip 12 may be directly applied to the repackaging structure 100. Alternatively, when the pitch between the corresponding pads 112 is an integral multiple of the pitch between the mounting pads 113, the chip holder or the circuit board originally matching the chip 12 may also be directly applied to the repackaging structure 100.

In this embodiment, the dielectric body 14 covers the chip 12 and a part of a surface of the substrate 11. A part of the dielectric body 14 is located between the conductive solder blocks 131. In this embodiment, the dielectric body 14 is formed by molding, but the disclosure is not limited thereto. In other embodiments, the dielectric body may also be formed in other suitable manners. In this embodiment, the electrical element 16 includes a conductive layer 161. The conductive layer 161 is disposed on the dielectric body 14. The conductive pillar 15 avoids the chip 12 and electrically connects the ground pad 114 of the substrate 11 and the conductive layer 161. Specifically, after the dielectric body 14 covering the chip 12 is formed, a through hole (i.e., a surface of conductive pillar 15 in the figure) avoiding the chip 12 is formed to penetrate the dielectric body 14 and reach the ground pad 114 of the substrate 11. Next, the conductive pillar 15 is formed in the through hole, and the conductive layer 161 is further formed on the dielectric body 14. As mentioned above, the conductive pillar 15 may be formed in a manner for forming a conductive via. In other words, it can be said that a combination of the conductive pillar 15 and the ground pad 114 penetrates the dielectric body 14. Furthermore, the conductive pillar 15 is electrically connected to the ground pad 114 of the substrate 11, and the conductive layer 161 is electrically connected to the conductive pillar 15.

Since the conductive layer 161 is electrically connected to the ground pad 114 through the conductive pillar 15, the conductive layer 161 is also grounded. Since there are the conductive layer 161 grounded and located above the chip 12 and the ground layer 1112 grounded and located below the chip 12, the chip 12 may be protected from external electromagnetic wave interference through electromagnetic interference shielding (EMI shielding). The conductive layer 161 may also have the function of dissipating heat. In this embodiment, although the above grounding is used to form an electromagnetic interference shielding, but the disclosure is not limited thereto. In other embodiments, the ground may also be changed to a specific potential.

In this embodiment, a dielectric body top view area R1 of the dielectric body 14 is larger than 100% of a chip top view area R2 of the chip 12 and smaller than or equal to 150% of the chip top view area R2, but the disclosure is not limited thereto. In other embodiments, the top view area of the dielectric body R1 of the dielectric body 14 may also be larger than 100% of the chip top view area R2 of the chip 12 and smaller than or equal to 120% of the chip top view area R2.

The repackaging structure 100 may further include a plurality of conductive solder blocks 17 disposed on the corresponding pads 112. The repackaging structure 100 may be mounted on and electrically connected to other chip holders or circuit boards through the corresponding pads 112 and the conductive solder blocks 17.

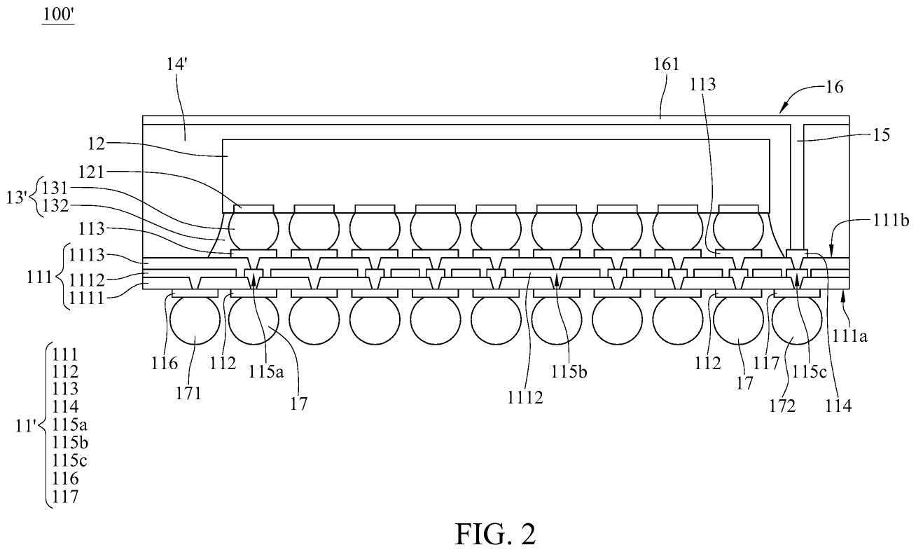

Please refer to FIG. 2. FIG. 2 is a schematic side cross-sectional view of a repackaging structure according to another embodiment of the disclosure. In this embodiment, the repackaging structure 100′ is similar to the repackaging structure 100 shown in FIG. 1, the same or similar elements use the reference numerals used in the repackaging structure 100 shown in FIG. 1, and the repeated descriptions are omitted appropriately.

As shown in FIG. 2, in this embodiment, the repackaging structure 100′ includes a substrate 11′, a chip 12, a buffer connection layer 13′, a dielectric body 14′, a conductive pillar 15 and an electrical element 16. The substrate 11′ includes a plate 111, a plurality of corresponding pads 112, a plurality of mounting pads 113, a ground pad 114, a plurality of conductive-via-connection structures 115a, 115b, 115c and a plurality of additional pads 116, 117. The plate 111 includes a first dielectric layer 1111, aground layer 1112 and a second dielectric layer 1113 stacked on one another sequentially. The corresponding pads 112, the additional pad 116 and the additional pad 117 are disposed on the lower surface 111a of the plate 111 and in contact with the first dielectric layer 1111. The additional pad 116 and the additional pad 117 are located around an array formed by the corresponding pads 112. The additional pad 116 is electrically connected with the ground layer 1112. The mounting pads 113 and the ground pad 114 are disposed on the upper surface 111b of the plate 111 and in contact with the second dielectric layer 1113. The ground pad 114 is electrically connected to the additional pad 117 through the conductive-via-connection structure 115c penetrating through the second dielectric layer 1113 and the first dielectric layer 1111. The conductive-via-connection structure 115c may be further electrically connected to the ground layer 1112.

The chip 12 is mounted on the substrate 11′ through the buffer connection layer 13′. The buffer connection layer 13′ includes a plurality of conductive solder blocks 131 and an underfill 132. The chip leads 121 are connected to the mounting pads 113 through the conductive solder blocks 131. The underfill 132 is disposed between the conductive solder blocks 131 and surround the conductive solder blocks 131. Therefore, the dielectric body 14′ may not be located between the conductive solder blocks 131.

The conductive layer 161 of the electrical element 16, the conductive pillar 15, the ground pad 114, the conductive-via-connection structure 115c, the additional pad 117, the ground layer 1112 and the additional pad 116 are all grounded. The repackaging structure 100′ may further include a plurality of conductive solder blocks 17, 171, 172. The conductive solder blocks 17 are disposed on the corresponding pads 112. The conductive solder block 171 is disposed on the additional pad 116. The conductive solder block 172 is disposed on the additional pad 117. The repackaging structure 100′ may be mounted on and electrically connected to other chip holders or circuit boards (not shown) through the conductive solder blocks 17, 171, 172. The chip holder or the circuit board may ground the conductive solder block 171 and the conductive solder block 172, so as to ground the additional pad 116 and the additional pad 117, such that the chip 12 may be protected from external electromagnetic wave interference through electromagnetic interference shielding produced by the conductive layer 161 and the ground layer 1112. The conductive layer 161 may also have the function of dissipating heat.

In this embodiment, the number of the mounting pads 113 is less than a sum of the number of the corresponding pads 112 and the number of the additional pads 116, 117. Furthermore, the additional pads 116, 117 are used for various non-signal functions. In addition, the mounting pads 113 may include a plurality of signal mounting pads 113 and a plurality of non-signal mounting pads 113, and the corresponding pads 112 may include a plurality of signal corresponding pads 112 and a plurality of non-signal corresponding pads 112. In this case, a number of the signal mounting pads 113 is equal to a number of the signal corresponding pads 112. The non-signal mounting pads 113 and the non-signal corresponding pads 112 may also be used for various non-signal functions such as grounding or power supply, but a total number of the non-signal mounting pads 113 is less than a total number of the non-signal corresponding pads 112.

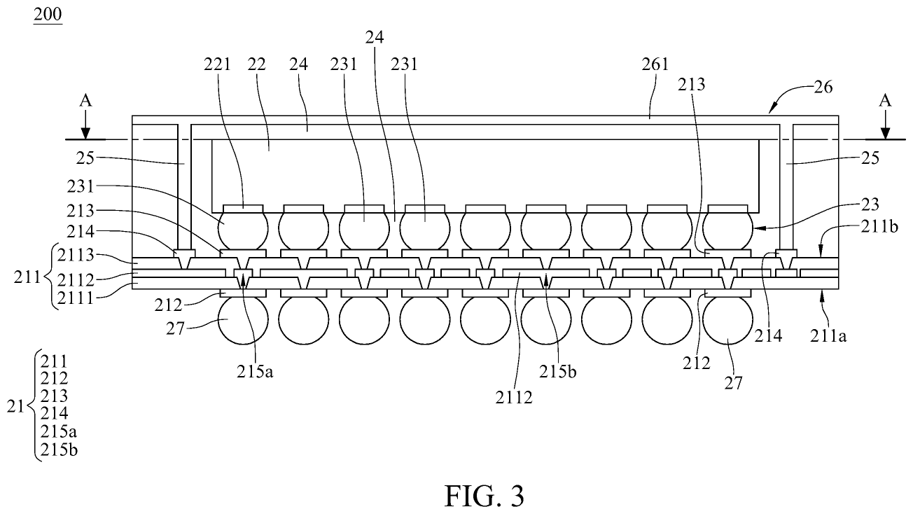

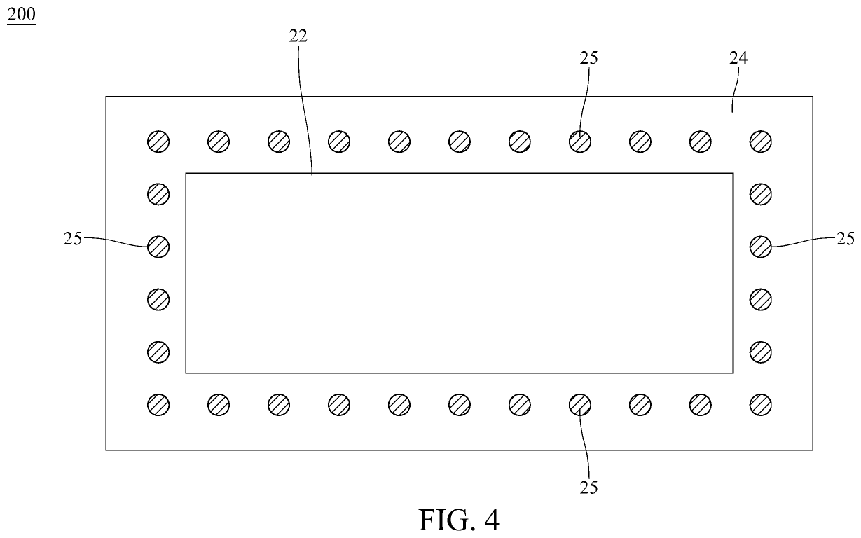

Please refer to FIG. 3 and FIG. 4. FIG. 3 is a schematic side cross-sectional view of a repackaging structure according to another embodiment of the disclosure. FIG. 4 is a schematic top cross-sectional view taken along the line A-A in FIG. 3. In this embodiment, the repackaging structure 200 is similar to the repackaging structure 100 shown in FIG. 1. In the following, the same or similar elements are labeled with similar reference numerals, and the repeated descriptions are omitted appropriately.

As shown in FIG. 3 and FIG. 4, in this embodiment, the repackaging structure 200 includes a substrate 21, a chip 22, a buffer connection layer 23, a dielectric body 24, a plurality of conductive pillars 25 and an electrical element 26. The substrate 21 includes a plate 211, a plurality of corresponding pads 212, a plurality of mounting pads 213, a plurality of ground pads 214 and a plurality of conductive-via-connection structures 215a, 215b. The plate 211 includes a first dielectric layer 2111, a ground layer 2112 and a second dielectric layer 2113 stacked on another sequentially. The corresponding pads 212 are disposed on the lower surface 211a of the plate 211 and in contact with the first dielectric layer 2111. The mounting pads 213 and the ground pads 214 are disposed on the upper surface 211b of the plate 211 and in contact with the second dielectric layer 2113. The ground pads 214 are located around an array formed by the mounting pads 213. The mounting pads 213 are electrically connected to the corresponding pads 212 through the conductive-via-connection structures 215a, 215b penetrating through the second dielectric layer 2113 and the first dielectric layer 2111. The conductive-via-connection structure 215b is electrically connected with the ground layer 2112. The ground pads 214 are electrically connected to the ground layer 2112.

The chip 22 is mounted on the substrate 21 through the buffer connection layer 23. The buffer connection layer 23 includes a plurality of conductive solder blocks 231. The chip leads 221 are connected to the mounting pads 213 through the conductive solder blocks 231. The dielectric body 24 covers the chip 22. A part of the dielectric body 24 is located between the conductive solder blocks 231. The conductive pillars 25 avoid the chip 22 and penetrate through the dielectric body 24. The conductive pillars 25 are electrically connected to the ground pads 214 of the substrate 21. The conductive pillars 25 are located around the chip 22. As shown in FIG. 4, the conductive pillars 25 are arranged in a manner surrounding the chip 22.

As shown in FIG. 3 and FIG. 4, a conductive layer 261 of the electrical element 26 is disposed on the dielectric body 24. The conductive layer 261 is electrically connected to the conductive pillars 25. The conductive layer 261 is electrically connected to the ground pads 214 through the conductive pillars 25. The conductive layer 261 of the electrical element 26, the conductive pillars 25, the ground pads 214 and the ground layer 2112 are all grounded. Since there are the conductive layer 261 grounded and located above the chip 22, the ground layer 2112 grounded and located below the chip 22, and the conductive pillars 25 grounded and located in front of, behind, at left and right of the chip 22, the chip 22 may be protected from external electromagnetic wave interference through electromagnetic interference shielding. The conductive layer 261 and the conductive pillars 25 may also have the function of dissipating heat.

The repackaging structure 200 may further include a plurality of conductive solder blocks 27. The conductive solder blocks 27 are disposed on the corresponding pads 212. The repackaging structure 200 may be mounted on and electrically connected to other chip holders or circuit boards (not shown) through the conductive solder blocks 27.

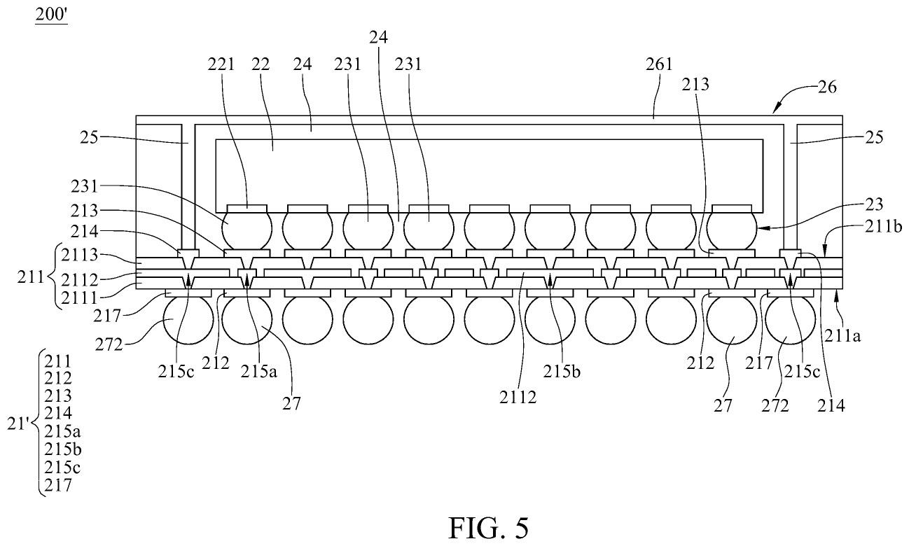

Please refer to FIG. 5. FIG. 5 is a schematic side cross-sectional view of a repackaging structure according to another embodiment of the disclosure. In this embodiment, the repackaging structure 200′ is similar to the repackaging structure 200 shown in FIG. 3, and the same or similar elements use the reference numeral used in the repackaging structure 200 shown in FIG. 3, and the repeated descriptions are omitted appropriately.

As shown in FIG. 5, in this embodiment, the repackaging structure 200′ includes a substrate 21′, a chip 22, a buffer connection layer 23, a dielectric body 24, a plurality of conductive pillars 25 and an electrical element 26. The substrate 21′ includes a plate 211, a plurality of corresponding pads 212, a plurality of mounting pads 213, a plurality of ground pads 214, a plurality of conductive-via-connection structures 215a, 215b, 215c and a plurality of additional pads 217. The plate 211 includes a first dielectric layer 2111, a ground layer 2112 and a second dielectric layer 2113 stacked on one another sequentially. The corresponding pads 212 and the additional pads 217 are disposed on the lower surface 211a of the plate 211 and in contact with the first dielectric layer 2111. The additional pads 217 are located around an array formed by the corresponding pads 212. The mounting pads 213 and the ground pads 214 are disposed on the upper surface 211b of the plate 211 and in contact with the second dielectric layer 2113. The ground pads 214 are located around an array formed by the mounting pads 213. The ground pads 214 are electrically connected to the additional pads 217 through the conductive-via-connection structures 215c penetrating through the second dielectric layer 2113 and the first dielectric layer 2111. The conductive-via-connection structures 215c may also further be electrically connected with the ground layer 2112.

The chip leads 221 of the chip 22 are mounted on and connected to the mounting pads 213 of the substrate 21′ through the conductive solder blocks 231 of the buffer connection layer 23. The dielectric body 24 covers the chip 22 and the conductive solder blocks 231. The conductive pillars 25 avoid the chip 22, penetrate through the dielectric body 24 and are electrically connected to the ground pads 214. The conductive pillars 25 are located around the chip 22. The conductive layer 261 of the electrical element 26 is disposed on the dielectric body 24 and electrically connected to the conductive pillars 25. The conductive layer 261 is electrically connected to the ground pads 214 through the conductive pillars 25.

The conductive layer 261 of the electrical element 26, the conductive pillars 25, the ground pads 214, the conductive-via-connection structures 215c, the additional pads 217 and the ground layer 2112 are all grounded. The repackaging structure 200′ may further include a plurality of conductive solder blocks 27, 272. The conductive solder blocks 27 are disposed on the corresponding pads 212. The conductive solder blocks 272 are disposed on the additional pads 217. The repackaging structure 200′ may be mounted on and electrically connected to other chip holders or circuit boards (not shown) through the conductive solder blocks 27, 272. The chip holder or the circuit board may ground the conductive solder blocks 272 and the additional pads 217, such that the chip 22 may further be protected from external electromagnetic wave interference through electromagnetic interference shielding. The conductive layer 261 and the conductive pillars 25 may also have the function of dissipating heat.

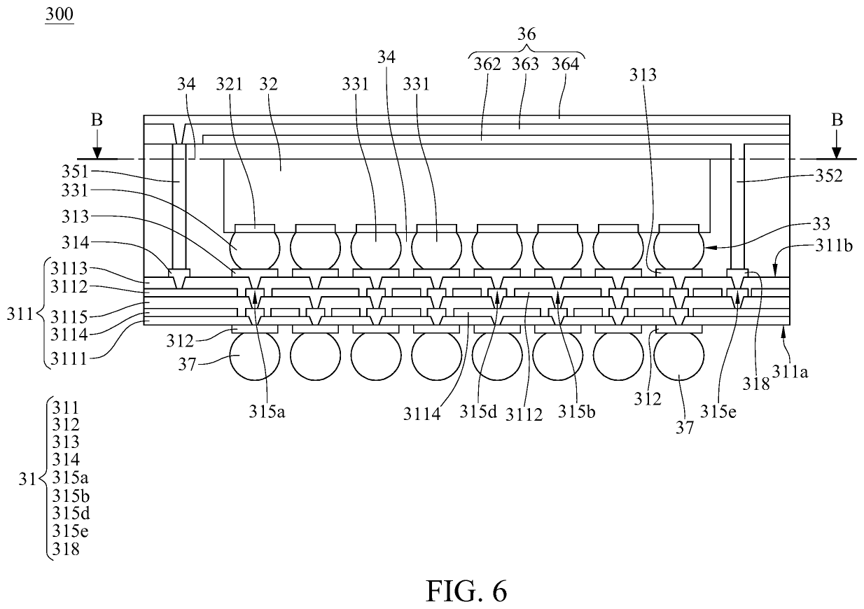

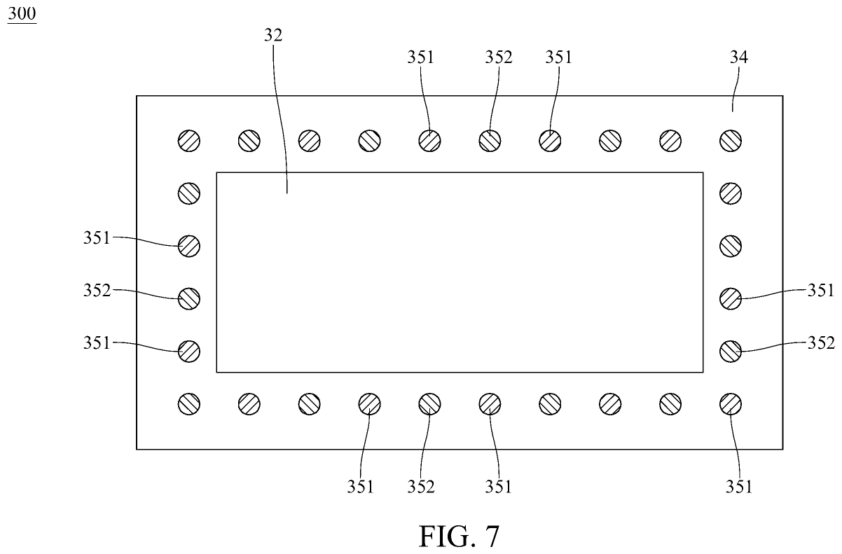

Please refer to FIG. 6 and FIG. 7. FIG. 6 is a schematic side cross-sectional view of a repackaging structure according to another embodiment of the disclosure. FIG. 7 is a schematic top cross-sectional view taken along the line B-B in FIG. 6. In this embodiment, the repackaging structure 300 is similar to the repackaging structure 100 shown in FIG. 1. In the following, the same or similar elements are labeled with similar reference numerals, and the repeated descriptions are omitted appropriately.

As shown in FIG. 6 and FIG. 7, in this embodiment, the repackaging structure 300 includes a substrate 31, a chip 32, a buffer connection layer 33, a dielectric body 34, a plurality of ground conductive pillars 351, a plurality of power conductive pillars 352 and an electrical element 36. The substrate 31 includes a plate 311, a plurality of corresponding pads 312, a plurality of mounting pads 313, a plurality of ground pads 314, a plurality of conductive-via-connection structures 315a, 315b, 315d, 315e and a plurality of power pads 318. The plate 311 includes a first dielectric layer 3111, a power layer 3114, a third dielectric layer 3115, a ground layer 3112 and a second dielectric layer 3113 stacked on one another sequentially. The corresponding pads 312 are disposed on the lower surface 311a of the plate 311 and in contact with the first dielectric layer 3111. The mounting pads 313, the ground pads 314 and the power pads 318 are disposed on the upper surface 311b of the plate 311 and in contact with the second dielectric layer 3113. The ground pads 314 and the power pads 318 are located around an array formed by the mounting pads 313. The mounting pads 313 are electrically connected to the corresponding pads 312 through the conductive-via-connection structures 315a, 315b, 315d penetrating through the second dielectric layer 3113, the third dielectric layer 3115 and the first dielectric layer 3111. The ground pads 314 are electrically connected to the ground layer 3112. The power pads 318 are electrically connected to the power layer 3114 through the conductive-via-connection structures 315e penetrating through the second dielectric layer 3113 and the third dielectric layer 3115.

The ground layer 3112 and the power layer 3114 are patterned. As a result, the conductive-via-connection structure 315a is electrically insulated from the ground layer 3112 and the power layer 3114. The conductive-via-connection structure 315b is electrically connected with the ground layer 3112 and electrically insulated from the power layer 3114. The conductive-via-connection structure 315d is electrically connected with the power layer 3114 and electrically insulated from the ground layer 3112. The conductive-via-connection structures 315e are electrically insulated from the ground layer 3112.

The chip leads 321 of the chip 32 are mounted on and connected to the mounting pads 313 of the substrate 31 through the conductive solder blocks 331 of the buffer connection layer 33. The dielectric body 34 covers the chip 32 and the conductive solder blocks 331. The ground conductive pillars 351 and the power conductive pillars 352 avoid the chip 32 and penetrate through the dielectric body 34. The ground conductive pillars 351 are electrically connected to the ground pads 314. The power conductive pillars 352 are electrically connected to the power pads 318. The ground conductive pillars 351 and the power conductive pillars 352 are located around the chip 32. As shown in FIG. 7, the ground conductive pillars 351 and the power conductive pillars 352 are arranged in a manner surrounding the chip 32. In this case, two of the ground conductive pillars 351 are respectively arranged on two sides of each of the power conductive pillars 352. In this embodiment, a number of the power conductive pillars 352 and a number of the conductive-via-connection structures 315e are both plural, but the disclosure is not limited thereto. In other embodiments, the number of the power conductive pillars 352 and the number of the conductive-via-connection structures 315e may also be one.

As shown in FIG. 6 and FIG. 7, in this embodiment, the electrical element 36 includes a first conductive layer 362, an insulating layer 363 and a second conductive layer 364. The first conductive layer 362 is disposed between the dielectric body 34 and the insulating layer 363. The insulating layer 363 is disposed between the first conductive layer 362 and the second conductive layer 364. The first conductive layer 362 is electrically connected to the power pads 318 through the power conductive pillars 352. The second conductive layer 364 is electrically connected to the ground pads 314 through the ground conductive pillars 351. The second conductive layer 364 which is grounded, the first conductive layer 362 which is connected to the power layer 3114, and the insulating layer 363 which is located therebetween may form a capacitor. The second conductive layer 364 of the electrical element 36, the ground conductive pillars 351, the ground pads 314 and the ground layer 3113 are all grounded. Since there are the second conductive layer 364 grounded and located above the chip 32, the ground layer 3112 grounded and located below the chip 32, and the ground conductive pillars 351 grounded and located in front of, behind, at left and right of the chip 32, the chip 32 may be protected from external electromagnetic wave interference through electromagnetic interference shielding. The second conductive layer 364, the ground conductive pillars 351 and the power conductive pillars 352 may also have the function of dissipating heat.

The repackaging structure 300 may further include a plurality of conductive solder blocks 37. The conductive solder blocks 37 are disposed on the corresponding pads 312. The repackaging structure 300 may be mounted on and electrically connected to other chip holders or circuit boards (not shown) through the conductive solder blocks 37.

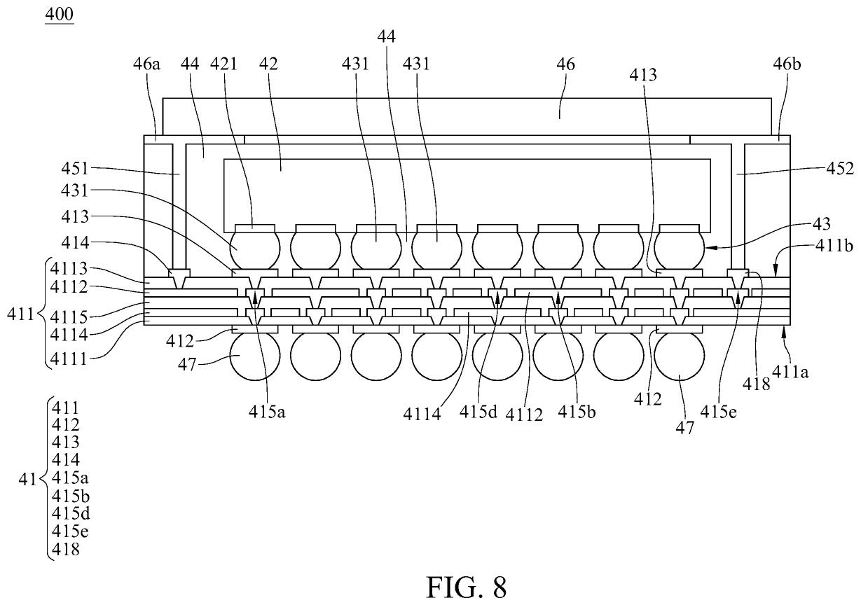

Please refer to FIG. 8. FIG. 8 is a schematic side cross-sectional view of a repackaging structure according to another embodiment of the disclosure. In this embodiment, the repackaging structure 400 is similar to the repackaging structure 100 shown in FIG. 1. In the following, the same or similar elements are labeled with similar reference numerals, and the repeated descriptions are omitted appropriately.

As shown in FIG. 8, in this embodiment, the repackaging structure 400 includes a substrate 41, a chip 42, a buffer connection layer 43, a dielectric body 44, a plurality of ground conductive pillars 451, a plurality of power conductive pillars 452 and an electrical element 46. The substrate 41 includes a plate 411, a plurality of corresponding pads 412, a plurality of mounting pads 413, a plurality of ground pads 414, a plurality of conductive-via-connection structures 415a, 415b, 415d, 415e and a plurality of power pads 418. The plate 411 includes a first dielectric layer 4111, a power layer 4114, a third dielectric layer 4115, a ground layer 4112 and a second dielectric layer 4113 stacked on one another sequentially. The corresponding pads 412 are disposed on the lower surface 411a of the plate 411 and in contact with the first dielectric layer 4111. The mounting pads 413, the ground pads 414 and the power pads 418 are disposed on the upper surface 411b of the plate 411 and in contact with the second dielectric layer 4113. The chip leads 421 of the chip 42 are mounted on and connected to the mounting pads 413 through a plurality of conductive solder blocks 431 of the buffer connection layer 43.

In this embodiment, the electrical element 46 is disposed on the dielectric body 44. The electrical element 46 is at least one capacitor element, at least one resistance element or other passive element. An electrode 46a and an electrode 46b of the electrical element 46 are respectively electrically connected to the ground conductive pillars 451 and the power conductive pillars 452. The electrical element 46 is electrically connected to the substrate 41 through the ground conductive pillars 451 and the power conductive pillars 452. In this embodiment, the ground pads 414 and the power pads 418 may be capacitor pads with different potentials for connecting the capacitor element.

The electrical element 46, the ground conductive pillars 451, the ground pads 414 and the ground layer 4113 are all grounded. Since there are the electrical element 46 grounded and located above the chip 42, the ground layer 4112 grounded and located below the chip 42, and the ground conductive pillars 451 grounded and located in front of, behind, at left and right of the chip 42, the chip 42 may be protected from external electromagnetic wave interference through electromagnetic interference shielding. The electrical element 46, the ground conductive pillars 451 and the power conductive pillars 452 may also have the function of dissipating heat.

The repackaging structure 400 may further include a plurality of conductive solder blocks 47. The conductive solder blocks 47 are disposed on the corresponding pads 412. The repackaging structure 400 may be mounted on and electrically connected to other chip holders or circuit boards (not shown) through the conductive solder blocks 47.

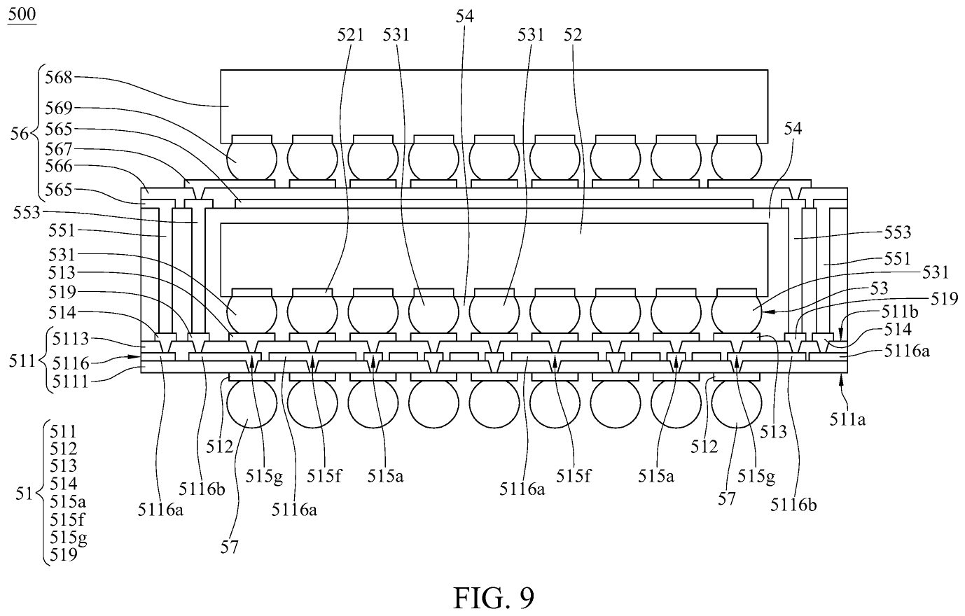

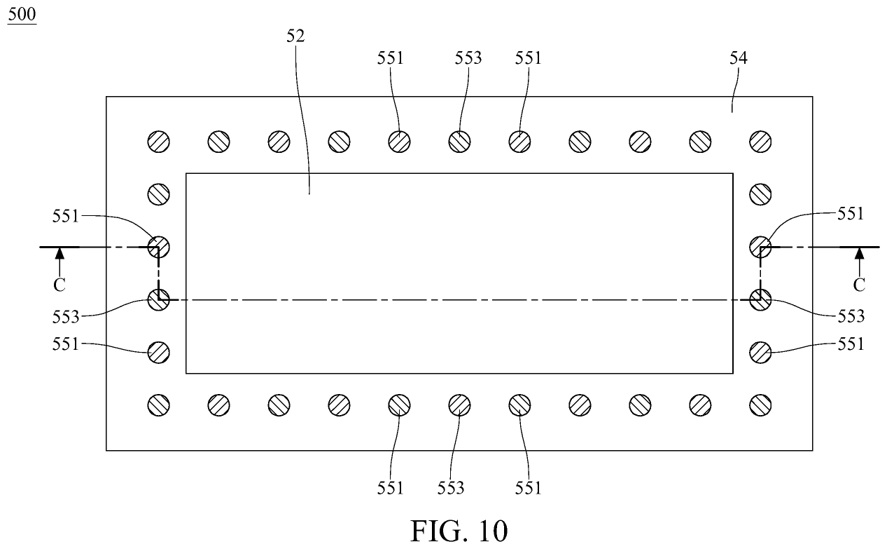

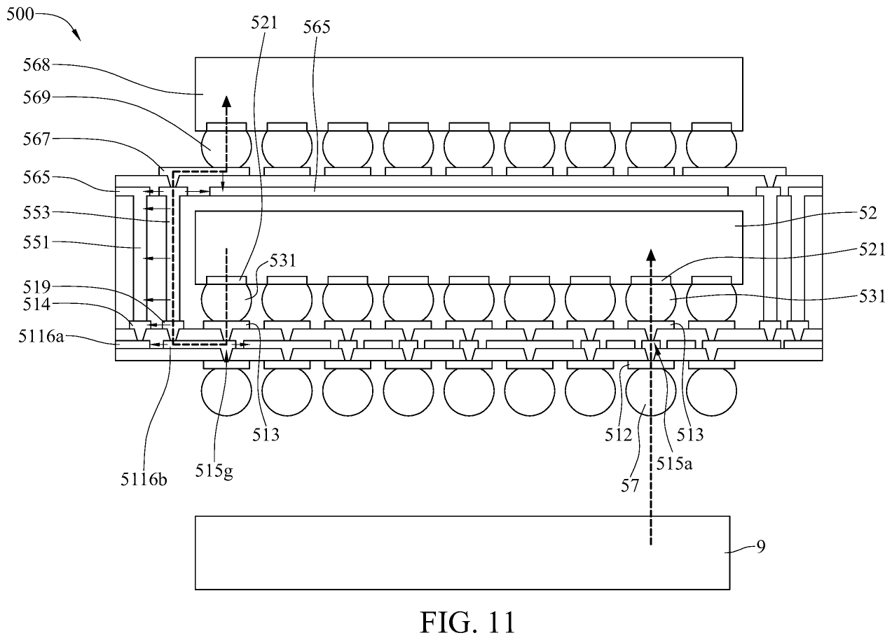

Please refer to FIG. 9 to FIG. 11. FIG. 9 is a schematic side cross-sectional view of a repackaging structure according to another embodiment of the disclosure. FIG. 10 is a schematic top cross-sectional view of the repackaging structure shown in FIG. 9, and FIG. 9 is a schematic side cross-sectional view taken along the line C-C in FIG. 10. FIG. 11 illustrates the application of the repackaging structure shown in FIG. 9. In this embodiment, the repackaging structure 500 is similar to the repackaging structure 100 shown in FIG. 1. In the following, the same or similar elements are labeled with similar reference numerals, and the repeated descriptions are omitted appropriately.

As shown in FIG. 9 to FIG. 10, in this embodiment, the repackaging structure 500 includes a substrate 51, a chip 52, a buffer connection layer 53, a dielectric body 54, a plurality of ground conductive pillars 551, a plurality of signal conductive pillars 553 and an electrical element 56. The substrate 51 includes a plate 511, a plurality of corresponding pads 512, a plurality of mounting pads 513, a plurality of ground pads 514, a plurality of conductive-via-connection structures 515a, 515f, 515g and a plurality of signal pads 519. The plate 511 includes a first dielectric layer 5111, a mixed layer 5116 and a second dielectric layer 5113 stacked in sequence. The corresponding pads 512 are disposed on the lower surface 511a of the plate 511 and in contact with the first dielectric layer 5111. The mounting pads 513, the ground pads 514 and the signal pads 519 are disposed on the upper surface 511b of the plate 511 and in contact with the second dielectric layer 5113.

The ground pads 514 and the signal pads 519 are located around an array formed by the mounting pads 513. The mounting pads 513 are electrically connected to the corresponding pads 512 through the conductive-via-connection structures 515a, 515f, 515g penetrating through the second dielectric layer 5113 and the first dielectric layer 5111. The mixed layer 5116 is patterned and divided into a ground layer 5116a and a signal layer 5116b located at the same layer. The ground pads 514 are electrically connected to the ground layer 5116a. The signal pads 519 are electrically connected to the signal layer 5116b.

The conductive-via-connection structures 515a are electrically insulated from the ground layer 5116a and the signal layer 5116b. The conductive-via-connection structures 515f are electrically connected with the ground layer 5116a and electrically insulated from the signal layer 5116b. The conductive-via-connection structures 515g is electrically connected with the signal layer 5116b and electrically insulated from the ground layer 5116a.

The chip leads 521 of the chip 52 are mounted on and connected to the mounting pads 513 through a plurality of conductive solder blocks 531 of the buffer connection layer 53. The dielectric body 54 covers the chip 52 and the conductive solder blocks 531. The ground conductive pillars 551 and the signal conductive pillars 553 avoid the chip 52 and penetrate through the dielectric body 54. The ground conductive pillars 551 are electrically connected to the ground pads 514. The signal conductive pillars 553 are electrically connected to the signal pads 519. The ground conductive pillars 551 and the signal conductive pillars 553 are located around the chip 52. As shown in FIG. 10, the ground conductive pillars 551 and the signal conductive pillars 553 are arranged in a manner surrounding the chip 52. In this case, two of the ground conductive pillars 551 are respectively arranged on two sides of each of the signal conductive pillars 553. In this embodiment, a number of the signal conductive pillars 553 and a number of the signal pads 519 are both plural, but the disclosure is not limited thereto. In other embodiments, the number of the signal conductive pillars 553 and the number of the signal pads 519 may also be one.

In this embodiment, the electrical element 56 is disposed on the dielectric body 54. The electrical element 56 includes a conductive layer 565, an insulating layer 566, a trace layer 567, an additional chip 568 and a plurality of conductive solder blocks 569.

The conductive layer 565 is disposed between the dielectric body 54 and the insulating layer 566. The insulating layer 566 is disposed between the conductive layer 565 the trace layer 567. The conductive layer 565 is electrically connected to the ground pads 514 through the ground conductive pillars 551. The trace layer 567 is electrically connected to the signal pads 519 through the signal conductive pillars 553. The additional chip 568 is mounted on the trace layer 567 through the conductive solder blocks 569. The conductive layer 565 is patterned so that the conductive layer 565 is electrically insulated from the signal conductive pillars 553.

The conductive layer 565 of the electrical element 56, the ground conductive pillars 551, the ground pads 514 and the ground layer 5116a are all grounded. Since there are the conductive layer 565 grounded and located above the chip 52, the ground layer 5116a grounded and located below the chip 52, and the ground conductive pillars 551 grounded and located in front of, behind, at left and right of the chip 52, the chip 52 may be protected from external electromagnetic wave interference through electromagnetic interference shielding. The conductive layer 565 may further avoid the chip 52 and the additional chip 568 from interfering with each other. The conductive layer 565, the ground conductive pillars 551 and the signal conductive pillars 553 may also have the function of dissipating heat.

As shown in FIG. 9 and FIG. 11, the repackaging structure 500 may further include a plurality of conductive solder blocks 57. The conductive solder blocks 57 are disposed on the corresponding pads 512. The repackaging structure 500 may be mounted on and electrically connected to other chip holders or circuit boards (not shown) through the conductive solder blocks 57 and further be electrically connected to the main central processing unit 9 (shown in FIG. 11).

As shown in FIG. 11, the main central processing unit 9 may input a first signal to the chip 52 through one of the conductive solder blocks 57, one of the corresponding pads 512, one of the conductive-via-connection structures 515a, one of the mounting pads 513, one of the conductive solder blocks 531 and one of the chip leads 521 (shown as a thick dashed arrow on the right side). The chip 52 may perform operations for this signal. After the chip 52 performs the operations, the chip 52 output a second signal from another chip leads 521. The second signal is input to the additional chip 568 through another one of the conductive solder blocks 531, another one of the mounting pads 513, one of the conductive-via-connection structures 515g, the signal layer 5116b, one of the signal pads 519, one of the signal conductive pillars 553, the trace layer 567 and one of the conductive solder blocks 569 (shown as a thick dashed arrow on the left side).

When the second signal passes through the conductive-via-connection structure 515g and the signal layer 5116b, lines of electric force (shown as thin solid arrows) toward the ground layer 5116a will be generated. When the second signal passes through the signal pad 519, lines of electric force (shown as thin solid arrows) toward the ground pads 514 will be generated. When the second signal passes through the signal conductive pillar 553, lines of electric force (shown as thin solid arrows) toward the ground conductive pillar 551 will be generated. When the second signal passes through the trace layer 567, lines of electric force (shown as thin solid arrows) toward the conductive layer 565 will be generated. As a result, impedances of the conductive-via-connection structure 515g, the signal layer 5116b, the signal pad 519, the signal conductive pillar 553 and the trace layer 567 that the second signal passes through may be matched to each other, and thus the second signal may be stabilized and have less loss.

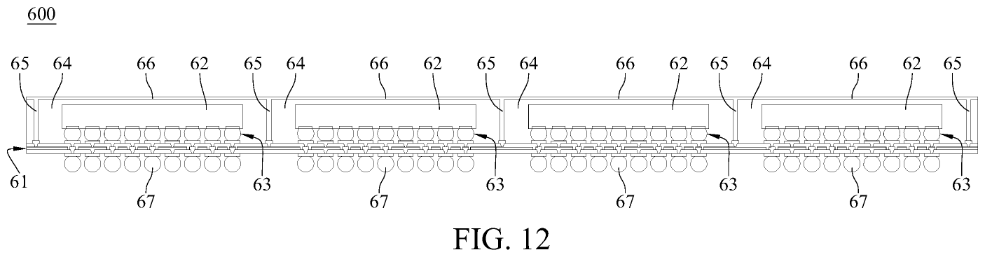

Please refer to FIG. 12. FIG. 12 is a schematic side cross-sectional view of a repackaging structure according to another embodiment of the disclosure. In this embodiment, the repackaging structure 600 is similar to the repackaging structure 100 shown in FIG. 1. In the following, the same or similar elements are labeled with similar reference numerals, and the repeated descriptions are omitted appropriately.

As shown in FIG. 12, in this embodiment, the repackaging structure 600 includes a substrate 61, a plurality of chips 62, a buffer connection layer 63, a dielectric body 64, a plurality of conductive pillars 65 and an electrical element 66. The chips 62 are mounted on the substrate 61 through the buffer connection layer 63. The dielectric body 64 covers the chips 62. The conductive pillars 65 avoid the chips 62 and penetrate the dielectric body 64. The conductive pillars 65 are located between the chips 62 and surround each of the chips 62. The conductive pillars 65 are electrically connected to the substrate 61.

The electrical element 66 is disposed on the dielectric body 64. The electrical element 66 is electrically connected to the conductive pillars 65. The electrical element 66 is electrically connected to the substrate 61 through the conductive pillars 65. The electrical element 66, the conductive pillars 65 and the substrate 61 are all grounded. Since there are the electrical element 66 grounded and located above the chips 62, the substrate 61 grounded and located below the chips 62, and the conductive pillars 65 grounded and located in front of, behind, at left and right of each of the chips 62, the chips 62 may be protected from external electromagnetic wave interference and avoided from interfering with each other through electromagnetic interference shielding. The electrical element 66 and the conductive pillars 65 may also have the function of dissipating heat. In this embodiment, some of the conductive pillars 65 are located between the chips 62, but the disclosure is not limited thereto. In other embodiments, there may also be no conductive pillar 65 disposed between the chips 62.

In this embodiment, the repackaging structure 600 may further include a plurality of conductive solder blocks 67. The conductive solder blocks 67 are disposed on the substrate 61. The repackaging structure 600 may be mounted on and electrically connected to other chip holders or circuit boards (not shown) through the conductive solder blocks 67.

As discussed above, in the repackaging structure in one embodiment of the disclosure, the chip is mounted on the substrate having the corresponding pads corresponding to the mounting pads, and the electrical element electrically connected to the substrate is disposed on the dielectric body covering the chip. Therefore, the functions of electrical element may be added while maintaining the original input and output status of the chip. When the electrical element is a conductive layer for grounding, the chip may be protected from external electromagnetic wave interference through electromagnetic interference shielding. In addition, when the electrical element includes the additional chip and the grounded conductive layer, the functions of the additional chip may be added to the repackaging structure, and the grounded conductive layer may also avoid the chip and the additional chip from interfering with each other. When the conductive pillar connecting the electrical element and the substrate is located around the chip and grounded, the chip may also be protected from external electromagnetic wave interference through electromagnetic interference shielding. Furthermore, the electrical element also has the effect of dissipating heat. Moreover, when the electrical element includes the first conductive layer which is connected with the power layer, the second conductive layer which is grounded, and the insulating layer which is located therebetween, the electrical element may form a capacitor, so that the repackaging structure has the function provided by the capacitor.

Although the disclosure is disclosed in the foregoing embodiments, it is not intended to limit the disclosure. All variations and modifications made without departing from the spirit and scope of the disclosure fall within the scope of the disclosure. For the scope defined by the disclosure, please refer to the attached claims.

1. A repackaging structure, comprising:
a substrate, comprising a plate, a plurality of mounting pads and a plurality of corresponding pads, wherein the plurality of corresponding pads and the plurality of mounting pads are disposed on opposite surfaces of the plate, and the plurality of corresponding pads correspond to the plurality of mounting pads;
at least one chip, mounted on the substrate and comprising a plurality of chip leads, wherein the plurality of chip leads are mounted on the plurality of mounting pads;
a dielectric body, covering the at least one chip;
an electrical element, disposed on the dielectric body; and
at least one conductive pillar, electrically connecting the electrical element and the substrate.

2. The repackaging structure according to claim 1, wherein the plurality of corresponding pads respectively correspond to the plurality of mounting pads.

3. The repackaging structure according to claim 1, wherein a number of the plurality of chip leads is equal to a number of the plurality of mounting pads, and the number of the plurality of mounting pads is equal to a number of the plurality of corresponding pads.

4. The repackaging structure according to claim 1, wherein a number of the plurality of chip leads is equal to a number of the plurality of mounting pads, and the number of the plurality of mounting pads is larger than a number of the plurality of corresponding pads.

5. The repackaging structure according to claim 1, wherein a number of the plurality of chip leads is equal to a number of the plurality of mounting pads, the number of the plurality of mounting pads is larger than a number of the plurality of corresponding pads, the plurality of chip leads comprise a plurality of signal leads and at least one other lead, and the plurality of signal leads are mounted on a part of the plurality of mounting pads corresponding to the plurality of corresponding pads in a one-on-one manner.

6. The repackaging structure according to claim 1, further comprising a buffer connection layer, wherein the at least one chip is mounted on the substrate through the buffer connection layer.

7. The repackaging structure according to claim 6, wherein the buffer connection layer comprises a plurality of conductive solder blocks.

8. The repackaging structure according to claim 7, wherein a portion of the dielectric body is located between is located between the plurality of conductive solder blocks.

9. The repackaging structure according to claim 7, wherein the buffer connection layer further comprises an underfill surrounding the plurality of conductive solder blocks.

10. The repackaging structure according to claim 1, wherein the substrate further comprises at least one ground pad, the electrical element comprises a conductive layer, the conductive layer is disposed on the dielectric body, and the conductive layer is electrically connected to the at least one ground pad through the at least one conductive pillar.

11. The repackaging structure according to claim 10, wherein the substrate further comprises a ground layer, and the at least one ground pad is electrically connected to the ground layer.

12. The repackaging structure according to claim 10, wherein a number of the at least one conductive pillar is plural, a number of the at least one ground pad is plural, the conductive pillars are electrically connected to the ground pads, and the conductive pillars are located around the at least one chip.

13. The repackaging structure according to claim 1, wherein the substrate further comprises at least one power pad and at least one ground pad, the electrical element comprises a first conductive layer, an insulating layer and a second conductive layer, the at least one conductive pillar comprises at least one ground conductive pillar and at least one power conductive pillar, the first conductive layer is disposed between the dielectric body and the insulating layer, the insulating layer is disposed between the first conductive layer and the second conductive layer, the first conductive layer is electrically connected to the at least one power pad through the at least one power conductive pillar, and the second conductive layer is electrically connected to the at least one ground pad through the at least one ground conductive pillar.

14. The repackaging structure according to claim 13, wherein the substrate further comprises a ground layer, and the at least one ground pad is electrically connected to the ground layer.

15. The repackaging structure according to claim 13, wherein a number of the at least one power conductive pillar is plural, a number of the at least one power pad is plural, the power conductive pillars are electrically connected to the power pads, a number of the at least one ground conductive pillar is plural, a number of the at least one ground pad is plural, the ground conductive pillars are electrically connected to the ground pads, the power conductive pillars and the ground conductive pillars are located around the at least one chip, and two of the ground conductive pillars are respectively arranged on two sides of each of the power conductive pillars.

16. The repackaging structure according to claim 1, wherein the electrical element is at least one capacitor element, a number of the at least one conductive pillar is plural, the at least one capacitor element are electrically connected to the substrate through the conductive pillars.

17. The repackaging structure according to claim 1, wherein the substrate further comprises at least one additional pad disposed on a same surface of the plate as the plurality of corresponding pads.

18. The repackaging structure according to claim 17, wherein the at least one additional pad is electrically connected to power or ground.

19. The repackaging structure according to claim 1, wherein the substrate further comprises at least one signal pad and at least one ground pad, the electrical element comprises a conductive layer, an insulating layer, a trace layer and an additional chip, the at least one conductive pillar comprises at least one ground conductive pillar and at least one signal conductive pillar, the conductive layer is disposed between the dielectric body and the insulating layer, the insulating layer is disposed between the conductive layer and the trace layer, the conductive layer is electrically connected to the at least one ground pad through the at least one ground conductive pillar, the trace layer is electrically connected to the at least one signal pad through the at least one signal conductive pillar, and the additional chip is mounted on the trace layer.

20. The repackaging structure according to claim 19, wherein the substrate further comprises a ground layer, and the at least one ground pad is electrically connected to the ground layer.

21. The repackaging structure according to claim 19, wherein a number of the at least one signal conductive pillar is plural, a number of the at least one signal pad is plural, the signal conductive pillars are electrically connected to the signal pads, a number of the at least one ground conductive pillar is plural, a number of the at least one ground pad is plural, the ground conductive pillars are electrically connected to the ground pads, the signal conductive pillars and the ground conductive pillars are located around the at least one chip, and two of the ground conductive pillars are respectively arranged on two sides of each of the signal conductive pillars.

22. The repackaging structure according to claim 1, wherein a top view area of the dielectric body is larger than 100% of a top view area of the at least one chip and smaller than or equal to 150% of the top view area of the at least one chip.

23. The repackaging structure according to claim 1, wherein the substrate further comprises a plurality of conductive-via-connection structures, each of the plurality of corresponding pads corresponds to and is electrically connected to each of the plurality of mounting pads through each of the plurality of conductive-via-connection structures.

24. A repackaging structure, comprising:
a substrate, comprising a plate, a plurality of mounting pads and a plurality of corresponding pads, wherein the plurality of corresponding pads and the plurality of mounting pads are disposed on opposite surfaces of the plate, and the plurality of corresponding pads correspond to the plurality of mounting pads;
at least one chip, mounted on the substrate and comprising a plurality of chip leads, wherein the plurality of chip leads are mounted on the plurality of mounting pads; wherein
a number of the plurality of chip leads is equal to a number of the plurality of mounting pads, the number of the plurality of mounting pads is larger than a number of the plurality of corresponding pads, the plurality of chip leads comprise a plurality of signal leads and at least one other lead, and the plurality of signal leads are mounted on a part of the plurality of mounting pads corresponding to the plurality of corresponding pads in a one-on-one manner.

25. A repackaging structure, comprising:
a substrate, comprising a plate, a plurality of mounting pads and a plurality of corresponding pads, wherein the plurality of corresponding pads and the plurality of mounting pads are disposed on opposite surfaces of the plate, and the plurality of corresponding pads correspond to the plurality of mounting pads;
at least one chip, mounted on the substrate and comprising a plurality of chip leads, wherein the plurality of chip leads are mounted on the plurality of mounting pads; wherein
the plurality of chip leads comprise a plurality of signal leads and at least one other lead, and each of the plurality of signal leads is mounted on one of the plurality of mounting pads corresponding to one of the plurality of corresponding pads.

26. The repackaging structure according to claim 24, further comprising:
a dielectric body, covering the at least one chip;
an electrical element, disposed on the dielectric body; and
at least one conductive pillar, electrically connecting the electrical element and the substrate.

27. The repackaging structure according to claim 25, further comprising:
a dielectric body, covering the at least one chip;
an electrical element, disposed on the dielectric body; and
at least one conductive pillar, electrically connecting the electrical element and the substrate.
